(19) United States
(12) Patent Application Publication
(10) Pub. No.: US 2009/0081894 A1
(43) Pub. Date: Mar. 26, 2009

(54) Insulative housing for configuring socket connector having pivotally mounted clip

(75) Inventors: Fang-Chu Liao, Tu-cheng (TW); Shuo-Hsiu Hsu, Tu-cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 12/284,377

(22) Filed: Sep. 22, 2008

(30) Foreign Application Priority Data
Sep. 22, 2007 (CN) 200720044134.8

(51) Int. Cl. H05K 1/00; B23P 19/00; H01R 13/62

(52) U.S. Cl. 439/81; 29/740; 439/345

(57) ABSTRACT

A socket connector (1) is provided with a pair of clips (13) on perimeter sidewalls (12) for providing sustain retention force to a packaged processor (2) independent from retention force applied to the heat sink so that forces applied to the heat sink are counteracted to reduce the risk of inadvertent processor removal or damage. While pressing portions (133) of the clips (13) are exerted a substantially downward vertical force by a user, the clips (13) are opened for receiving the packaged processor (2). After the user stop pressing the pressing portions (133), the resilient force of the clips (31) push the latching portions (131) fixing on the side edge of the packaged processor (2) for performing the aforementioned purpose.

### BACKGROUND OF THE INVENTION

1. Field of the Invention

The present invention relates in general to the field of processor socket connector, and more particularly to a system and method for retaining a central processing unit in a socket connector.

2. Description of Related Art

As the requirement of operating process and compatible on information handling system grows, corresponding socket connector types always vary as well for complying with types of processors. A land grid array (LGA) socket connector mounted on a motherboard has become a major socket connector in computer market. U.S. Pat. No. 7,207,808 issued to Ma on Apr. 24, 2007 and U.S. Pat. No. 7,044,746 issued to Copper on May 16, 2006 disclose similar type of LGA socket connectors. Pads of a packaged processor wrap with LGA contact terminals restrained in passageways of an insulative housing of a LGA socket connector for achieving electrical connection between the packaged IC and the motherboard socket connector.

Because operating speed of a new generation processor is growing faster and faster, the heat generated by the processor is raising higher and higher. In order to effectively reduce the surface temperature of the CPU within an acceptable operating range, it is unavoidable (indispensable) to attach a heat sink over an upper surface of the processor for heat dissipation. U.S. Pat. No. 6,970,354 issued to Villanueva on Nov. 29, 2005 discloses a processor socket connector having a group of processor retaining mechanism. Please refer to FIG. 1 and FIG. 2, the processor socket connector fastened on a motherboard 102 comprises processor socket 104 for receiving a processor 106 and surrounded by a processor retaining assembly 110. A retention frame 1102 and a retention cover 1104 configure the retaining assembly 110. A retention frame 1102 couples to a motherboard 102 around the processor socket 104 to support movement of the processor cover 1104 between opened and closed positions. A securing device hinge 1106 rotationally couples the processor cover 1104 to the retention frame 1102 and a curved retention tongue 1108 are pressed by a lever 120 for locking the processor cover 1104 in the closed position to restrict movement of the processor from the socket. A heat sink 112 contacts the processor 106 through an opening 1110 in the processor cover 1104. If the heat sink 112 moves due to forces applied to an information handling system, the forces are translated to the processor 106 by the coupling force of the thermal grease between the heat sink 112 and the processor 106. That is why '354 provides a retaining assembly prevents inadvertent removal of a processor from a processor socket by forces exerted on an information handling system that are translated from a heat sink to the processor by the coupling of thermal grease between the heat sink and the processor.

Although a retaining assembly is able to avoid a processor out of a processor socket while disconnecting a heat sink from an upper surface of a processor having thermal grease therebetween for transmitting heat generated by the processor to heat sink for heat dissipation. However the material of the retaining assembly 110 is made of metal and configured by the retaining frame 1102, retaining cover 1104 and hinge 1106. Therefore, it is desired to offer an improved retainer for simplification of manufacturing process and cost reduction.

### BRIEF SUMMARY OF THE INVENTION

Therefore a need has arisen for a method and system which retains a processor in a circuit board socket to counteract forces applied by the heat sink to the processor.

In accordance with the present invention, a method and system are provided which substantially reduce the disadvantages and problems associated with previous methods and systems for retaining an information handling system processor and heat sink in place. A processor retainer assembly provides retention force to the processor independent from retention force applied to the heat sink so that forces applied to the heat sink are counteracted to reduce the risk of inadvertent processor removal or damage.

One example of an important technical advantage is that a processor is positively retained in a circuit board independent from a heat sink to counteract forces applied to the processor by the heat sink through the coupling of thermal grease. Separate processor retention prevents processor movement induced by heat sink movement translated to the processor through thermal grease. For instance, the insulative housing of a socket connector having a base and a plural of perimeter sidewalls extending from the base to define a inner cavity for receiving a packaged IC. The opposite perimeter sidewalls further comprising corresponding rotating clips for attaching to the packaged integrated circuit. The rotating clips can be opened by pressing the pressing portion of the clips or closed by relaxing the same. More importantly, while the clips are in closed positions, the processor and the heat sink can be separated each other without distortion or damage on the processor due to the rotating clips' retention.

Another example of an important technical advantage of the present invention is that a single assembly for simplification of manufacturing process and cost reduction provides an insulative housing and face-to-face rotating clips. Incorporation of the insulative housing and rotating clips in a single assembly not only shrinks the using space, but also reduces the cost of information handling system assembly when compared with assembly of multiple parts. As a result, such advantages are suitable in an application of portable systems, for instance laptop PC, mobile phone or the like.

Other objects, advantages and novel features of the invention will become more apparent from the following detailed description of the present embodiment when taken in conjunction with the accompanying drawings.

### BRIEF DESCRIPTION OF THE DRAWINGS

The features of this invention which are believed to be novel are set forth with particularity in the appended claims. The invention, together with its objects and the advantages thereof, may be best understood by reference to the following description taken in conjunction with the accompanying drawings, in which like reference numerals identify like elements in the figures and in which:

FIG. 1 illustrates an isometric view of a conventional socket connector mounted a CPU chip thereon;

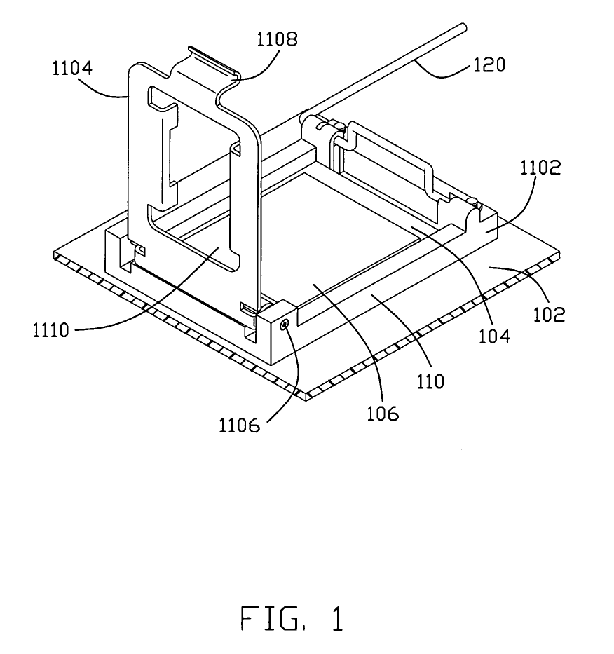

FIG. 2 illustrates a combined view of a conventional socket connector mounted a CPU chip thereon shown in FIG. 1 and corresponding heat sink;

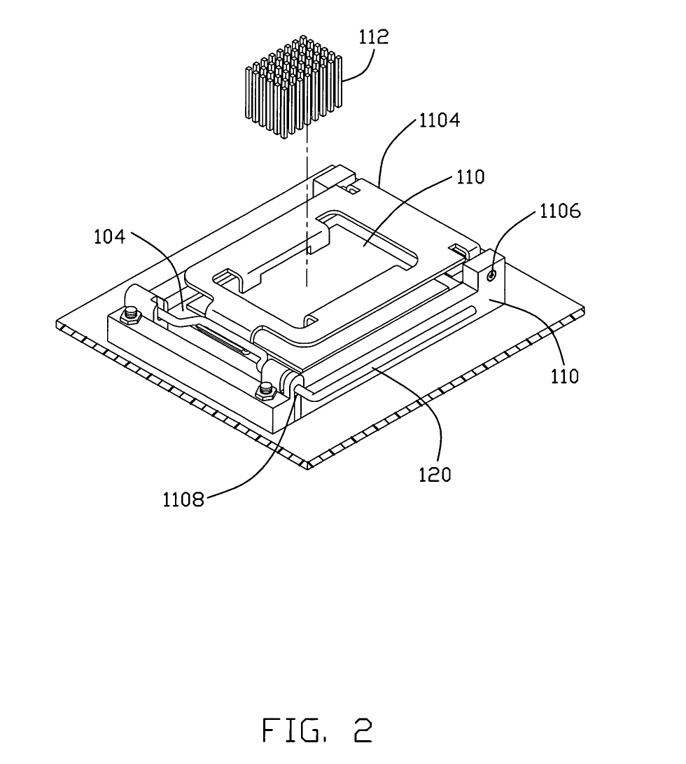

FIG. 3 illustrates an isometric exploded view of an insulative housing of a socket connector and a processor chip according to the preferred embodiment of the present invention;

FIG. 4 illustrates a rear view of the insulative housing of the socket connector shown in FIG. 3;

FIG. 5 illustrates an enlarged view of area A shown in FIG. 4;

FIG. 6 illustrates a combined view of the socket connector and a CPU chip shown in FIG. 3.

FIG. 7 illustrates a flow chart of assembling a packaged processor in a socket connector in accordance with the preferred embodiment of the present invention.

### DETAILED DESCRIPTION OF THE INVENTION

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

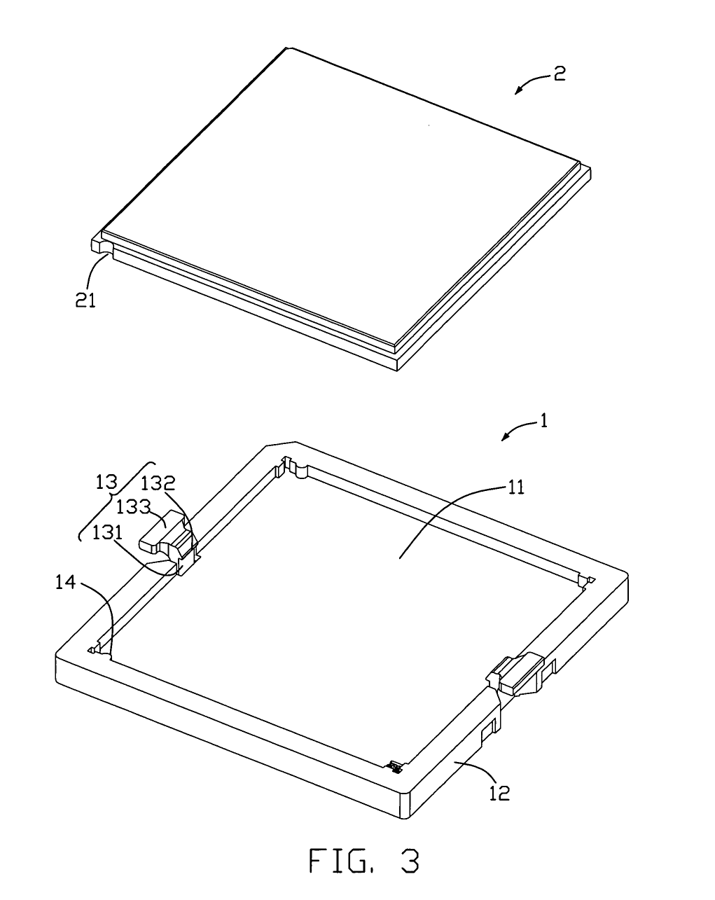

FIG. 3 illustrates an isometric exploded view of an insulative housing of a socket connector 1 and a processor chip 2 according to the preferred embodiment of the present invention. The socket connector 1 comprises a base 11 and a plurality of perimeter sidewalls 12 extending upward from the base 11 to define an inner cavity for receiving the packaged processor 2. In addition that, there is at least one pair of rotating clips 13 on opposite perimeter sidewalls 12 for retaining the packaged processor 2, or releasing the same therefrom. The rotating clip 13 may further classified into three portions, the first one is linking portion 131, the second one is latching portion 132 and the final one is pressing portion 133. The linking portion 131 is used for pivotally connecting the rotating clip 13 with the base 11. The latching portion 132 is able to utilize for fixing the packaged processor 2. As for the pressing portion 133, it should be recognized that the pressing portion 133 is for accepting a downward vertical force F to make the clip is in opened condition. As soon as the downward vertical force F is released, the clip 13 would attach both side edges of the packaged processor 2. Consequently, the user may successfully remove heat sink pasted on the upper surface of the packaged processor 2 via thermal grease without risk of the processor out of the socket connector during the heat sink removing process.

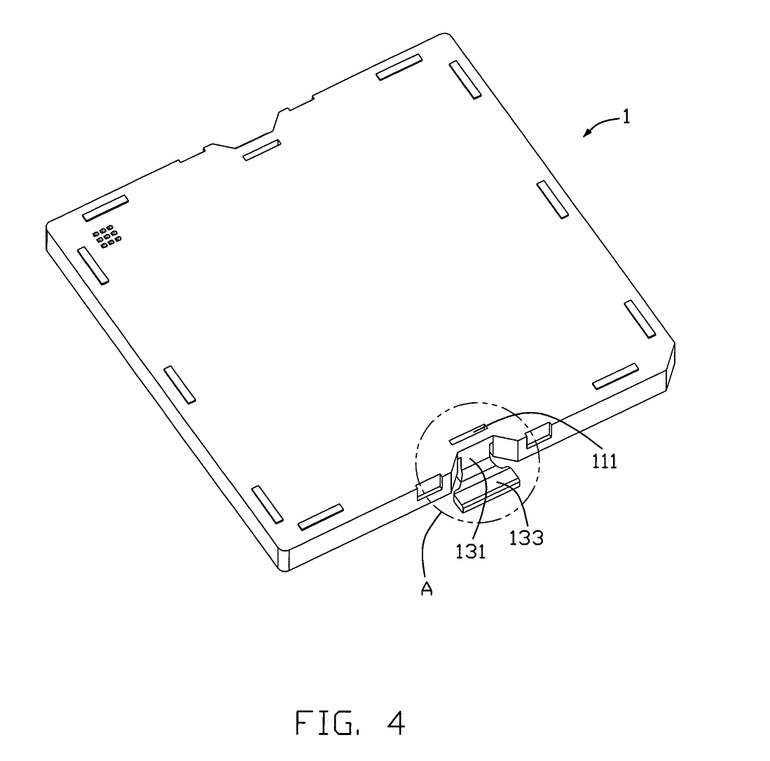

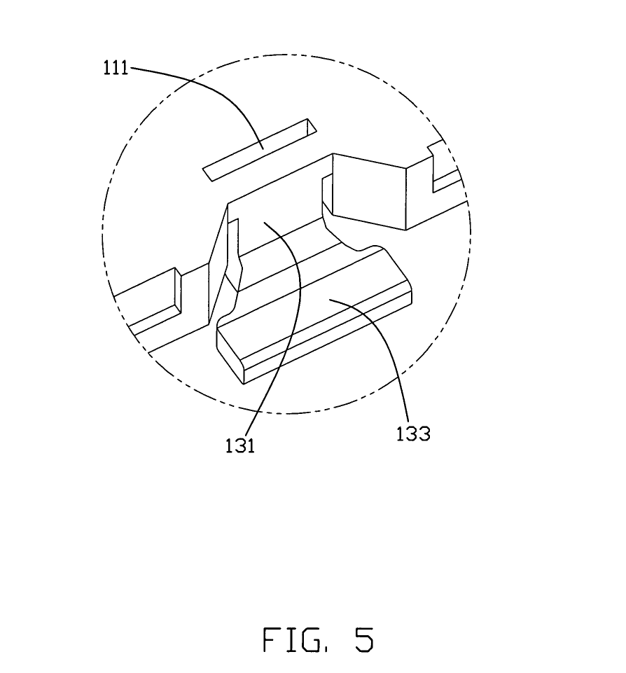

FIG. 4 displays a rear surface of the insulative housing shown in FIG. 3. FIG. 5 further illustrates an enlarged view of location A shown in FIG. 4. Refer to FIG. 4 and FIG. 5, there are a plurality of blind opening 111 formed on vicinity of side edge of the perimeter sidewalls for releasing the stress resulted from the downward vertical force F exerted on the pressing portions 133 while a user want to open the insulative housing of the socket connector 1.

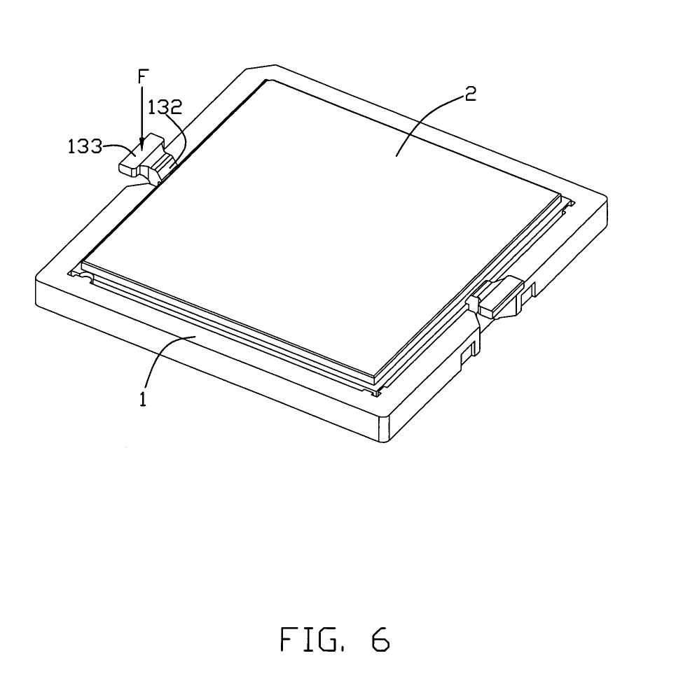

FIG. 6 illustrates an isometric view of the combination of the insulative housing 1 and the packaged processor 2. The orientation of the packaged processor 2 and the insulative housing of the socket connector 1 relies on a guiding recess 21 on a side edge of the packaged processor 2 and a guiding protrusion 14 on an inner side edge of the insulative housing of the socket connector 1 for ensuring the packaged processor 2 is put on the insulative housing in a right orientation. The shape of the guiding protrusion 14 can be any shape, for example bump, semi-columnar, strip, lump, semi-spherical, trapezoid, prism, block or the like.

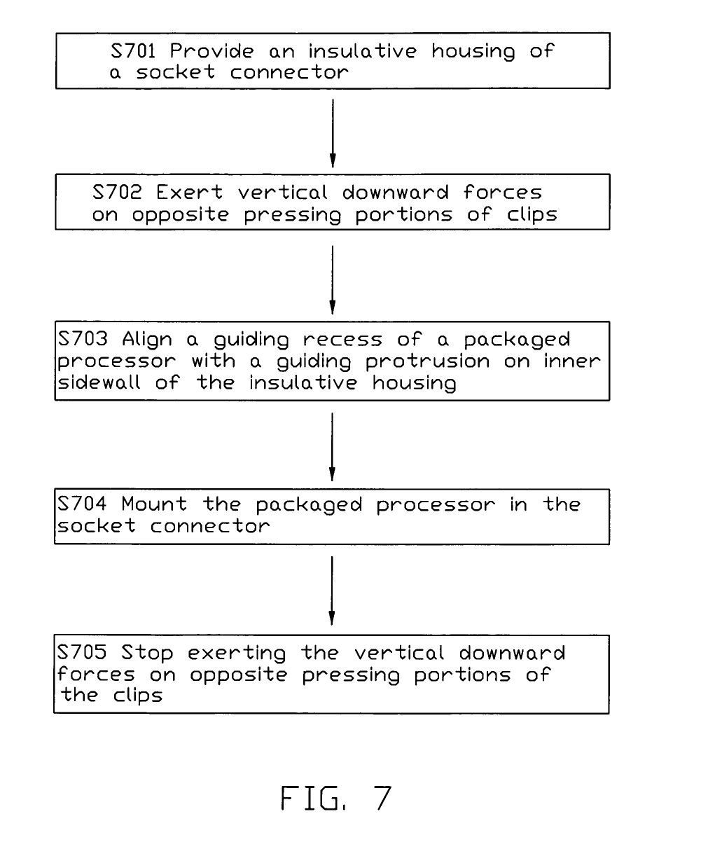

FIG. 7 illustrates a flow chart for assembling an electrical device in a socket connector according to the preferred embodiment of the present invention. Refer to S701, a user should take a socket connector 1 in accordance with the preferred embodiment of the present invention. In S702, the user exerts vertical downward forces F on opposite pressing portions 133 of clips 133 for preparing to receive a packaged processor 2 in the socket connector 2. After that, S703 illustrates a step of aligning a guiding recess of a packaged processor with a guiding protrusion on inner sidewall of the insulative housing of the socket connector. Furthermore, S704 shows that a user mounts the packaged processor in the socket connector while the socket connector 1 in the opened status. Finally, as shown in S705, the user stop exerting the vertical downward forces F on the opposite pressing portions 133 of the clips 13, then latching portions 132 of the clips 13 consequently latch the side edge of the packaged processor 2 due to resilient forces come from the clips 13.

Although the present invention has been illustrated and described with respect to exemplary embodiment thereof, it should be understood by those skilled in the art that the various changes, omissions and additions may be made therein and thereto without departing from the spirit and scope of the present invention as set forth in the appended claims.

What is claimed is:

1. A socket connector for receiving a packaged integrated circuit, comprising:
an insulative housing having a base and a plural of perimeter sidewalls extending from the base to define a inner cavity for receiving a packaged IC, the opposite perimeter sidewalls further comprising a pair of clips rotationally mounted on sidewalls of the housing.

2. A socket connector as claimed in claim 1, wherein each of the clips is composed of latching portion, pressing portion and linking portion.

3. A socket connector as claimed in claim 2, wherein the latching portions of the clips is used either for fixing the packaged integrated circuit in a closed position or for loosing the same in an opened position.

4. A socket connector as claimed in claim 3, wherein each pressing portion of the clips is able to be exerted a downward vertical force for keeping each latching portion in the opened position.

5. A socket connector as claimed in claim 2, wherein the clips extending from the base through linking portion to form the latching portion and pressing portion.

6. A socket connector as claimed in claim 1, wherein the rear surface of the base further comprises a plural of blind openings.

7. A socket connector as claimed in claim 1, wherein inner sidewalls of the perimeter sidewalls further comprise at least one guiding protrusion for ensuring the package integrated circuit is placed in a correcting orientation.

8. A socket connector as claimed in claim 7, wherein sidewalls of the packaged integrated circuit comprises at least one guiding recess for matching up with the guiding protrusion on the inner sidewalls of the perimeter sidewall.

9. A socket connector as claimed in claim 8, wherein the shape of guiding protrusion can be one of selected group of consisting of bump, semi-columnar, strip, lump, semi-spherical, trapezoid, prism and block.

10. A method for assembling a packaged integrated circuit in a socket connector comprising the steps of:
(a) providing an insulative housing of the socket connector, at least two inner sidewall of opposite perimeter sidewalls including respective clips placed in a manner of face-to-face for clipping the packaged integrated circuit.
(b) exerting vertical downward forces on opposite pressing portions of the clips at the same time for keeping the clips in an opened position.
(c) aligning the packaged integrated circuit with the socket connector and mounting the packaged integrated circuit into the socket connector.
(d) releasing the clips such that the clips retaining both sides of the packaged integrated circuit.

11. The method as claimed in claim 9, wherein the clips further comprising respectively latching portions and linking portions, the latching portions are used for fixing the mounted packaged integrated circuit and the linking portion are used for connecting the latching portions and pressing portions with the base.

12. The method as claimed in claim 9, wherein the clips are portions of the insulative housing.

13. A method as claimed in claim 9, wherein the rear surface of the base further comprises a plural of blind openings.

14. A method as claimed in claim 9, wherein inner sidewalls of the perimeter sidewalls further comprise at least one guiding protrusion for ensuring the package integrated circuit is placed in a correcting orientation.

15. A method as claimed in claim 14, wherein sidewalls of the packaged integrated circuit comprises at least one guiding recess for matching up with the guiding protrusion on the inner sidewalls of the perimeter sidewall.

16. A method as claimed in claim 15, wherein the shape of guiding protrusion can be one of selected group of consisting of bump, semi-columnar, strip, lump, semi-spherical, trapezoid, prism and block.

17. An electrical connector assembly comprising:
an insulative housing defining a base with a plurality of side walls commonly defining a receiving cavity therein;
a plurality of contacts disposed in the base with contacting sections extending upwardly into the receiving cavity;
a pair of latches located on two opposite side walls in a deflectable manner, each of said latches defining a locking section extending into the receiving cavity and a pressing section extending outwardly away from the receiving cavity opposite to said locking section.

18. The electrical connector assembly as claimed in claim 17, wherein said pressing section extend beyond a contour of said housing defined by said side walls in a top view.

19. The electrical connector assembly as claimed in claim 17, wherein said latches are unitarily formed with the housing, and the base defines two through holes in vertical alignment with the locking sections of the latches.

20. The electrical connector assembly as claimed in claim 17, wherein a cutout, which is recessed from a contour of said housing defined by said side walls in a top view, is formed under the pressing section of each of said latches in the corresponding side wall for provision of elasticity of the corresponding latch thereof.
